(19) United States
(12) Patent Application Publication
(10) Pub. No.: US 2006/0154495 A1
(43) Pub. Date: Jul. 13, 2006

(54) Device for cleaning the surface of a component

(75) Inventors: Jean Hue, Meylan (FR); Etienne Quesnel, Meylan (FR); Florian Evers, Berlin (DE)

Correspondence Address: PEARNE & GORDON LLP, 1801 EAST 9TH STREET, SUITE 1200, CLEVELAND, OH, 44114-3108, US

(73) Assignee: COMMISSARIAT A L'ENERGIE ATOMIQUE, paris 1 5 eme (FR)

(21) Appl. No.: 10/516,277

(22) PCT Filed: Jun. 12, 2003
(86) PCT No.: PCT/FR03/01768

§ 371 Date: Nov. 29, 2004

(30) Foreign Application Priority Data
Jun. 13, 2002 (FR) 02 07263

(51) Int. Cl. B08B 3/12; H01L 21/324; B08B 6/00

(52) U.S. Cl. 438/795; 134/1

(57) ABSTRACT

A detached particle capture means by laser (4) allows them to be attracted and prevented from dropping back better than a traditional blow-off flushing means would. Various categories of attractive forces may be implemented. It will also be possible to use a particle destruction means, like a second high-power laser above the worked surface (3).

The subject of this invention is a device for cleaning a surface of a component, particularly an optical or electronic component, so as to remove from it a number of so-called contaminating particles that would render it unsuitable for the service for which it is intended. These particles may be inorganic or organic in nature.

A known means for cleaning various objects is a laser beam. This technique has been proposed for cleaning the front elevations of buildings, micro-electronic components like integrated circuits of optical discs, or components intended for optical uses. The power of the beam detaches the particles from the surface.

Thought has also been given to removing the detached particles from the component surface in such a way as to prevent them from subsequently dropping back. A flushing gas is frequently employed. Another process uses the vaporization of a liquid previously deposited on the surface to be decontaminated by the laser itself: the vapour lifts the particles.

An illustration of these techniques is constituted by U.S. Pat. No. 5,024,968 A.

A number of inadequacies have however been observed in the processes already proposed, since some at least of the detached particles drop back onto the cleaned surface, not far from the place from which they originate. An improved means of eliminating these particles is therefore desired and that is the subject of this invention.

In the aforementioned prior patent, it is endeavoured to remove the lifted particles by flushing using a surface grazing gas current. Such flushing is insufficient since the detached particles are borne in flight over the component for only a short distance, which explains how they are able easily to drop back.

The proposed means of elimination with the invention is a means of particle capture or destruction which can take various forms, but which is placed in front of the surface (and therefore close to it) so as to produce either an attraction on the particles if the means is a capture means, or an immediate elimination of the particles is the means is a destruction means.

The characteristic of the capture by attraction means is that their action on the particles is not relaxed until capture is achieved contrary to the action of the flushing means. Some of these means consist of suction means or structures polarized relative to the component so as to produce the attractive force on the detached particles. Destruction means may include the beam of a second laser different from the previous one. The proximity of the capture or destruction means to the surface to be cleaned guarantees a good result from the process.

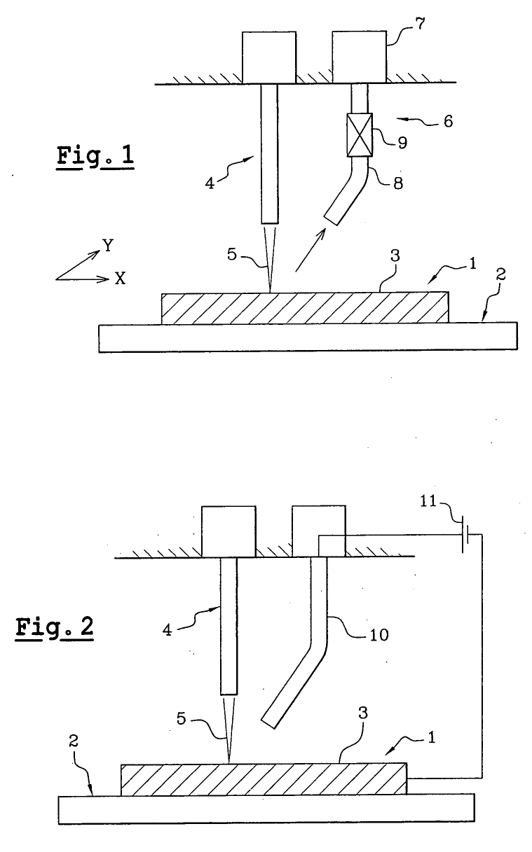

The different aspects of the invention will now be described by means of FIGS. 1 to 8, which all show a particular embodiment thereof, while not ruling out others.

Reference will now be made to the figures. In FIG. 1, a component to be decontaminated is given the reference number 1, and it is laid on a table 2 that can be moved in a plane X-Y so as to displace the component 1, and more exactly its upper surface 3 to be decontaminated, in front of a piece of equipment which includes a laser 4 emitting a beam 5 directed towards the surface 3, and a suction device 6 including a pump 7 and a pipe 8 directed towards the surface 3 and more exactly towards the strike point of the beam 5; a filter 9 may be added into the pipe 8 or downstream from the pump 7.

The beam 5 detaches the contaminating particles from the surface 3, and the suction current draws them towards the pipe 8 and causes them to pass through the filter 9 where they are permanently retained. The complete decontamination process consists in moving the table 2 and the retained component 1 until the whole zone for cleaning of the surface 3 has been swept by the beam 5.

In FIG. 2, the suction device is replaced by a pointer 10, which is of a conductive material and therefore able to be polarized by a voltage generator 11 relative to the component 1. The polarization direction is selected so that the particles detached and ionised by the power of the laser 4 are attracted by the pointer 10 and deposit themselves thereon. The distance between the pointer 10 and the surface 3 is a few hundred micrometres, for a potential difference of a few tens of volts to a few kilovolts.

It will be observed that this embodiment is particularly advantageous for components with a surface with raised parts, and particularly with cavities, since the attraction means may be made so as to remain very close to the laser beam 5 and to follow it even into tight cavities. All the embodiments of the invention including particle capture therefore comprise a polarization component in the shape of a pointer, which attracts the particles detached from the surface in the best conditions. The pointed shape has the extra advantage of strengthening the polarization field where it is required. The polarization may be direct or alternating. Finally, the field application is localized where it is useful.

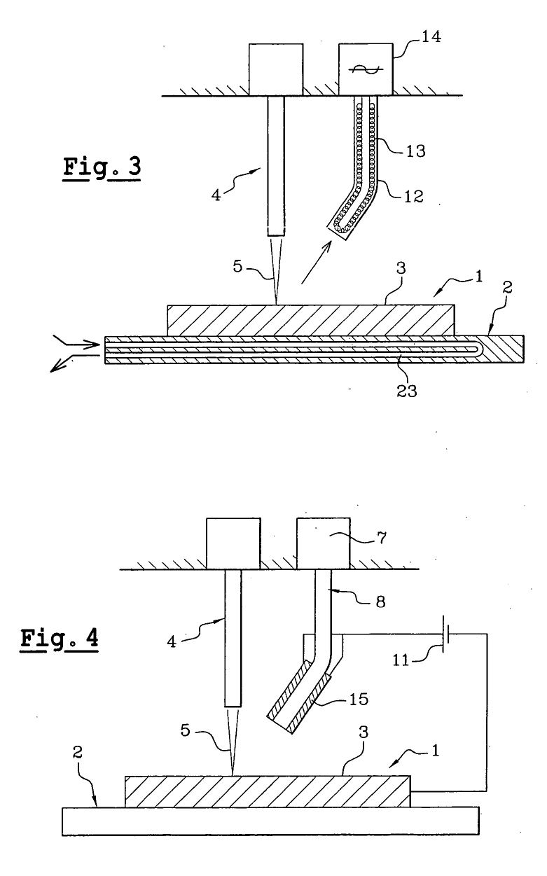

Everything that has been said above also applies to the embodiment in FIG. 3, whether the electrostatic pointer 10 of the previous embodiment is replaced by a pointer 12 heated, for example, by an electric resistance 13 which it contains and which is passed through by an alternating current coming from a source 14. This is the phenomenon known as thermophoresis, which is used to cause the detached particles to be attracted by the pointer 12. The effect may to advantage be enhanced by cooling the component 1, for example by Peltier effect or by a liquefied gas current which is able to flow in a pipe 23 hollowed out in the table 2.

The attractive means described up till now are not ruled out, nor are those to be described.

It is thus possible to combine attraction by suction with attraction by electric or thermal polarization, as is shown in FIG. 4. Once again we have a pump 7 and a pipe 8, but the end of the pipe 8 comprises polarized plates 15 (which may form the pipe or simply be added onto it) similar to those of the pointer 10. The detached particles are sucked up into the pipe 8 both by the suction force and by the electrostatic force, and they may be deposited on the plates 15 when this latter force is sufficient. Once again we have in this case a voltage generator 11 to polarize the plates 15 relative to the component 1.

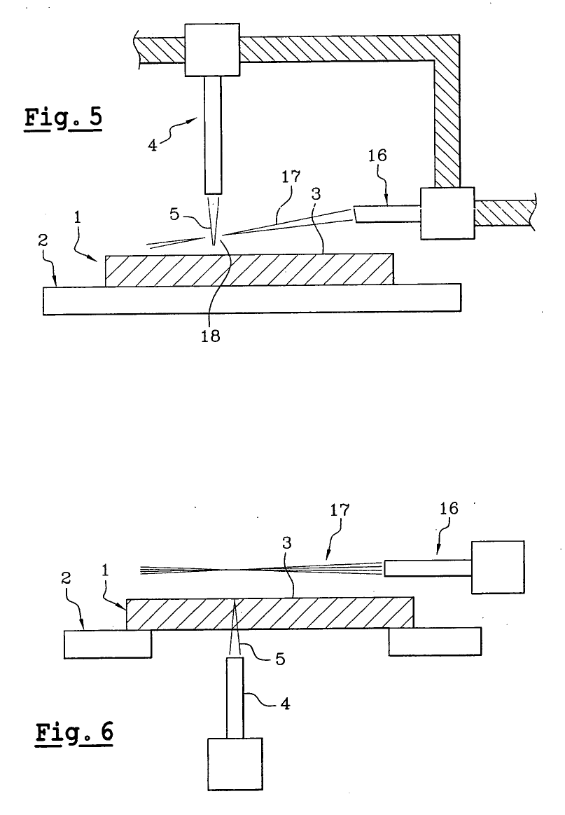

Another means used to prevent contamination includes a second laser supplying a power different from the first and designed to destroy the detached particles. Whereas the first laser 4 is able to provide a beam 5 in pulses from 0.1 ns to 100 ns at a rate above a few Hz and a wavelength in the ultraviolet, the second laser will for example be of continuous operation at a few hundred watts or a few kilowatts. The wavelength will be selected so as to be at best absorbed by the body constituting the particles. FIG. 5 shows such an arrangement, where alongside the first laser 4, we find a second laser 16 which emits a grazing incidence beam 17 above the upper surface 3 in such a way as to touch the detached particles which fly up to this height. To advantage, the beam 17 is focused in one or two directions and comprises a focal point 18 where it cuts the beam 5 of the first laser 4, so that the power is the most concentrated at the point where the particles detach and where their destruction is therefore most advisable.

Some variants of the invention have still to be mentioned. It is not therefore necessary for the laser 4 detaching the particles to be directed towards the contaminated surface 3: FIG. 6 shows that it can very well be directed towards the opposite side of the surface, provided the component 1 is transparent to the beam 5. The laser 4 is then separated from the particle capture or destruction means (which may be the same as previously, for example a second laser 16) by the component 1.

Lastly, FIG. 7 shows that to the previous device may be added a device for observing the phenomenon that may consist of an additional laser 18 emitting an illuminating beam 29 which is diffused towards an optical device that may include a reflecting mirror 20 and a lens 21 which focuses this beam towards a camera 22. This device in particular allows the particles to be displayed and then destroyed by following, on the image, the outcome of the cleaning. Thus it is not always necessary to sweep the whole surface but to direct the beam only onto the particles when these are few and far between. A particle capture or elimination means similar to the previous ones is added to the device, but has not been shown here for reasons of clarity. It should be noted that the laser beams are not necessarily perpendicular to the surfaces to be cleaned or observed.

The previous embodiments can be modified in the detail, and others would be possible: so it is that capture and destruction means could be combined, so as for example to attract the particles by a suction means towards their place of destruction, by the high-energy laser or the like.

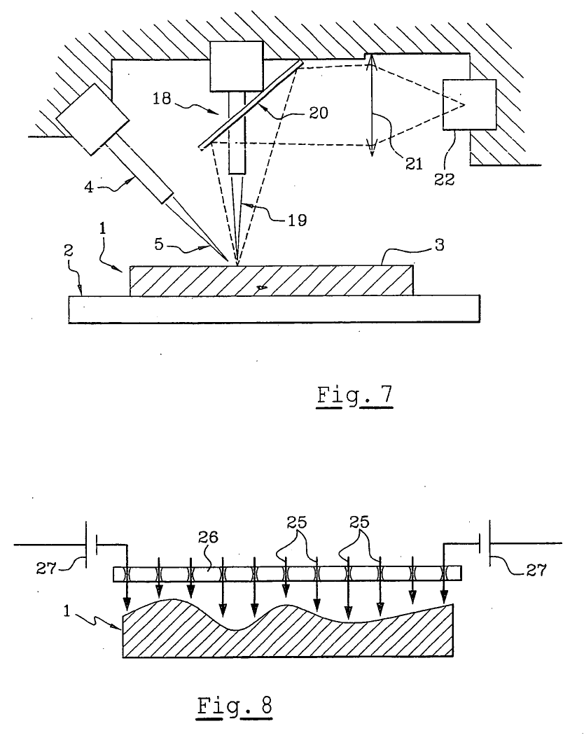

A particular embodiment of certain interest is described in FIG. 8. It includes a bank of electrically or thermally polarized pointers 25 similar to the pointers 10 or 12. The pointers 25 depend on a common support 26 and are all directed in parallel towards the surface to be decontaminated of the component 1. Screw or force fitting of the pointers 25 into bores in the common support 26 allows the forward movement of each of the pointers 25 to be adjusted separately and therefore allows them all to be placed at the required distance from the surface of the component 1 even if it has raised parts, so as to set up a sufficient field without running the risk of scraping the surface and in accordance also with the nature of the field, that of the particles and the conditions of implementation of the process. The field source 27 may be different for each of the pointers 25 or common. As previously, it may be thermal, electric, alternating or direct.

This embodiment may be employed with effect in micro-electronics, on laminated substrates composed of etched layers. The pointers 25 are aligned perpendicular to a direction of the raised parts of the surface of the component 1, and placed in this direction.

When the pointers 10, 22 or 25 are polluted, they are either cleaned or replaced.

1. Device for cleaning a surface (3) of a component, particularly an optical or electronic component, by a laser directed towards said surface, characterized in that it includes, placed in front of the surface, a means of capturing particles detached from the surface which includes a structure polarized relative to the component, characterized in that the structure comprises at least one pointer pointed towards the surface.

2. Device for cleaning a surface (3) of a component, particularly an optical or electronic component, by a laser directed towards said surface, including, placed in front of the surface, a means for destroying particles detached from the surface.

3. Device for cleaning a surface (3) of a component according to claim 1, characterized in that the capture means additionally comprises a suction means (6) including a pipe (8) pointing towards the surface (3).

4. Device for cleaning a surface (3) of a component according to claim 1, characterized in that the structure is polarized thermally relative to the component (1).

5. Device for cleaning a surface (3) of a component according to claim 1, characterized in that the structure is polarized electronically relative to the component (1).

6. Device for cleaning a surface of a component according to claim 1, characterized in that the particle capture means includes a set of several pointers polarized relative to the component.

7. Device for cleaning a surface of a component according to claim 3, characterized in that the structure (15) which is polarized either thermally or electrically relative to the component ()1 forms the pipe (8) or is adjacent to the pipe.

8. Device for cleaning a surface of a component according to claim 2, characterized in that the destruction means is a beam (17) of a second laser (16).

9. Device for cleaning a surface of a component according to claim 8, characterized in that the second laser is placed in grazing incidence in front of the surface.

10. Device for cleaning a surface of a component according to claim 8 or 9, characterized in that the second laser is focused on a point where it cuts the beam (5) of the laser (4) directed towards the surface (3).

11. Device for cleaning a surface of a component according to claim 2, characterized in that with the destruction means is combined a means of capturing the particles detached from the surface.
